(19) United States
(12) Patent Application Publication
(10) Pub. No.: US 2026/0160793 A1
(43) Pub. Date: Jun. 11, 2026

(54) ELECTRICAL ARC FLASH DETECTION

(71) Applicant: Chevron U.S.A. Inc., San Ramon, CA (US)

(72) Inventors: Jonathan Wayne Kitchel, Friendswood, TX (US); Jawad Butros Zaid, Pearland, TX (US); Eric William Glaude, Richmond, TX (US)

(21) Appl. No.: 18/710,167

(22) PCT Filed: Mar. 6, 2024
(86) PCT No.: PCT/US2024/018744

§ 371 Date: May 14, 2024

Related U.S. Application Data
(60) Provisional application No. 63/469,754, filed on May 30, 2023.

(51) Int. Cl. G01R 31/12; G08B 21/18; G08C 17/02; H02H 1/00; H02H 3/10

(52) U.S. Cl. CPC G01R 31/1218; G08B 21/182; G08C 17/02; H02H 1/0023; H02H 3/10

(57) ABSTRACT

A portable arc flash detection device includes a light sensor configured to detect a flash of light. The portable arc flash detection device further includes a controller configured to receive sensor data from the light sensor. The portable arc flash detection device also includes a wireless communication unit, where the controller is configured to send a flash detection message wirelessly via the wireless communication unit in response to determining that an intensity level of the flash of light exceeds a threshold lux level. The flash detection message indicates whether the flash of light is detected.

### FIELD

The present disclosure generally relates to arc flash detection and in particular to portable arc flash detection device, method, and system.

### BACKGROUND

In some systems, electrical arcs can produce extremely high temperatures, blast pressures, high intensity light, and ultrasonic acoustics and the expulsion of shrapnel projectiles and molten metal and may be associated with significant hazards to electrical workers. Some arc flash detection systems that can detect electrical arcs flashes may be permanently installed in electrical systems and can be helpful in quickly clearing faults associated with electrical arcs. Quickly clearing faults associated with electrical arcs can result in reduced hazards to electrical workers, reduced damage to electrical equipment, and shorter equipment and system downtime. Although some arc flash detection systems are readily installed permanently as part of a new construction, adding such permanent arc flash detection systems to an existing electrical installation can be excessively expensive and thus undesirable. Thus, a solution that enables arc flash detection without excessive cost and installation challenges may be desirable.

### SUMMARY

The present disclosure generally relates to arc flash detection and in particular to portable arc flash detection device, method, and system. In an example embodiment, a portable arc flash detection device includes a light sensor configured to detect a flash of light. The portable arc flash detection device further includes a controller configured to receive sensor data from the light sensor. The portable arc flash detection device also includes a wireless communication unit, where the controller is configured to send a flash detection message wirelessly via the wireless communication unit in response to determining that an intensity level of the flash of light exceeds a threshold lux level. The flash detection message indicates whether the flash of light is detected.

In another example embodiment, an arc flash detection and power control system includes a portable arc flash detection device that includes a light sensor configured to detect a flash of light at an electrical device, a controller configured to receive sensor data from the light sensor, and a wireless communication unit. The controller is configured to send a flash detection message wirelessly via the wireless communication unit in response to determining that an intensity level of the flash of light exceeds a threshold lux level. The flash detection message indicates whether the flash of light is detected. The arc flash detection and power control system further includes a breaker control system configured to receive the flash detection message wirelessly and to trip a circuit breaker at least based on the flash detection message such that power is disconnected from the electrical device.

In yet another example embodiment, a method of arc flash detection and power control includes receiving, by a breaker control system, a flash detection message wirelessly, where the flash detection message indicates whether a flash of light having an intensity level that exceeds a threshold lux level is detected by a portable flash detection device at an electrical device. The method further includes determining, by the breaker control system, whether the flash detection message indicates that the flash of light is detected. The method also includes tripping, by the breaker control system, a circuit breaker based on at least the flash detection message such that power is disconnected from the electrical device.

These and other aspects, objects, features, and embodiments will be apparent from the following description and the claims.

### BRIEF DESCRIPTION OF THE DRAWINGS

Various aspects of the invention will now be described with reference to the following figures in which the same reference numerals are used to designate corresponding parts throughout each of the several views.

FIG. 1 illustrates an arc flash detection and power control system that includes portable arc detection devices according to an example embodiment;

FIG. 2 illustrates a power control system of the arc flash detection and power control system of FIG. 1 according to an example embodiment;

FIG. 3 illustrates a portable arc flash detection device of the arc flash detection and power control system of FIG. 1 according to an example embodiment;

FIG. 4 illustrates the portable arc flash detection device of FIG. 3 according to an example embodiment;

FIG. 5 illustrates the portable arc flash detection device of FIG. 3 according to another example embodiment;

FIG. 6 illustrates the portable arc flash detection device of FIG. 4 attached to clothing according to an example embodiment;

FIG. 7 illustrates an attachment apparatus for attaching the portable arc flash detection device of FIG. 3 to clothing according to an example embodiment;

FIG. 8 illustrates the portable arc flash detection device of FIG. 3 attached to clothing using the attachment apparatus of FIG. 7 according to an example embodiment;

FIG. 9 illustrates an attachment apparatus for attaching the portable arc flash detection device of FIG. 3 to clothing according to another example embodiment;

FIG. 10 illustrates the portable arc flash detection device of FIG. 3 attached to clothing using the attachment apparatus of FIG. 9 according to an example embodiment;

FIG. 11 illustrates the portable arc flash detection device of FIG. 3 attached to clothing according to another example embodiment;

FIG. 12 illustrates the portable arc flash detection device 300 of FIG. 3 attached to clothing according to another example embodiment; and

FIG. 13 illustrates an arc flash detection and power control method according to an example embodiment.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different figures may designate like or corresponding but not necessarily identical elements.

### DETAILED DESCRIPTION OF THE EMBODIMENTS

In the following paragraphs, example embodiments will be described in further detail with reference to the figures. In the description, well known components, methods, and/or processing techniques are omitted or briefly described. Furthermore, reference to various feature(s) of the embodiments is not to suggest that all embodiments must include the referenced feature(s).

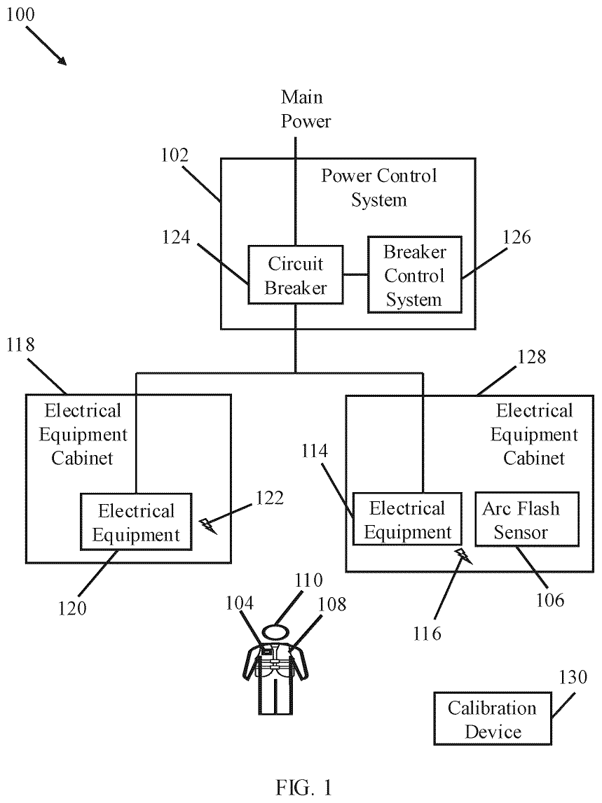

FIG. 1 illustrates an arc flash detection and power control system 100 that includes portable arc flash detection devices 104, 106 according to an example embodiment. In some example embodiments, the arc flash detection and power control system 100 includes a power control system 102 and the portable arc flash detection devices 104, 106. The power control system 102 may receive flash detection messages from the portable arc flash detection devices 104, 106 and disconnect power from electrical equipment.

In some example embodiments, the portable arc flash detection device 104 may detect a flash of light and transmit a flash detection message wirelessly indicating whether a flash of light is detected. For example, the portable arc flash detection device 104 may detect a flash of light, such as an arc flash 122, inside an electrical equipment cabinet 118. The portable arc flash detection device 104 may determine whether a flash of light exceeds a threshold lux level and may transmit the flash detection message if the flash of light exceeds threshold lux level. Because the lux level of an electrical arc flash is much higher than lux level of lights from typical light sources, such as light from light fixtures, a flashlight from a camera, direct sunlight, etc., the threshold lux level may be set high enough to avoid mistakenly identifying light from such other sources as an arc flash. For example, the threshold lux level may be set to at least 50 k lux, or higher.

In some example embodiments, the portable arc flash detection device 104 may be removably attached to the clothing 108 of a person 110. The portable arc flash detection device 104 may be removably attached to the clothing 108 by a clip and/or using an attachment apparatus such as Velcro or a magnet. The portable arc flash detection device 104 may be attached to the clothing 108 such that the portable arc flash detection device 104 points toward the inside the electrical equipment cabinet 118 when the person 110 is working on the electrical equipment 120 housed inside the electrical equipment cabinet 118. For example, the electrical equipment 120 may include a downstream circuit breaker and/or other electrical equipment, and the person 110 may be a technician performing energized work on the electrical equipment 120. To illustrate, the person 110 may perform tasks such as racking a breaker in or out, troubling shooting an energized component, taking voltage and other related measurements, etc. that may result in electrical arcing and the arc flash 122.

In some example embodiments, because multiple power control systems may be in the same area, the portable arc flash detection device 104 may first pair with the breaker control system 126 of the power control system 102 to establish wireless communication before sending a flash detection message. For example, the portable arc flash detection device 104 may transmit the flash detection message wirelessly using a wireless communication technology, such as LoRaWAN, Bluetooth Low Energy (BLE), Wi-Fi, etc. After pairing with the breaker control system 126, the portable arc flash detection device 104 may send the flash detection message, for example, upon detecting the arc flash 122 or another arc flash.

In some example embodiments, the portable arc flash detection device 106 may detect a flash of light and transmit a flash detection message wirelessly indicating whether a flash of light is detected. For example, the portable arc flash detection device 106 may detect a flash of light, such as an arc flash 116, inside an electrical equipment cabinet 128. The portable arc flash detection device 106 may determine whether a flash of light exceeds a threshold lux level and may transmit the flash detection message if the flash of light exceeds threshold lux level. Because the lux level of an electrical arc flash is much higher than lux level of lights from typical light sources, such as light from light fixtures, a flashlight from a camera, direct sunlight, etc., the threshold lux level may be set high enough to avoid mistakenly identifying light from such other sources as an arc flash. For example, the threshold lux level may be set to at least 50 k lux, or higher.

In some example embodiments, the portable arc flash detection device 106 may be attached to an electrical equipment cabinet 128 that houses the electrical equipment 114. For example, the electrical equipment 114 may include a downstream circuit breaker and/or other electrical equipment. The portable arc flash detection device 106 may be removably attached to the electrical equipment 114 magnetically and pointing toward an area inside the electrical equipment cabinet 128 where electrical work may be performed on the electrical equipment 114. For example, a technician may perform energized work on the electrical equipment 114 such as racking a breaker in or out, troubling shooting an energized component, taking voltage and other related measurements, etc. that may result in an electrical arcing and the arc flash 116 associated with the electrical arcing.

In some example embodiments, because multiple power control systems may be in the same area, the portable arc flash detection device 106 may first pair with the breaker control system 126 of the power control system 102 to establish wireless communication before sending a flash detection message. For example, the portable arc flash detection device 106 may transmit the flash detection message wirelessly using a wireless communication technology, such as LoRaWAN, BLE, Wi-Fi, etc. After pairing with the breaker control system 126, the portable arc flash detection device 106 may send the flash detection message, for example, upon detecting the arc flash 116 or another arc flash.

In some example embodiments, the power control system 102 includes a circuit breaker 124 and a breaker control system 126. The breaker control system 126 may receive flash detection messages from the portable arc flash detection devices 104, 106 and disconnect power from downstream electrical equipment such as electrical equipment 114, 120. For example, the breaker control system 126 may receive a flash detection message from the portable arc flash detection device 104 and determine whether the flash detection message indicates that a flash of light is detected by the portable arc flash detection device 104. If the flash detection message indicates that a flash of light is detected, the breaker control system 126 may disconnect power from the electrical equipment 114, 120. For example, the breaker control system 126 may include a protection relay or a shunt trip device to trip the circuit breaker 124. In general, the breaker control system 126 may trip the circuit breaker 124 electrically or electromechanically such that main power (e.g., power from a power utility or from a generator) is disconnected from the electrical equipment 114, 120. That is, the breaker control system 126 may control the circuit breaker 124 such that the breaker controlled power, which corresponds to the main power when the circuit breaker 124 is on, is turned off.

In some example embodiments, the breaker control system 126 may pair with one or both of the portable arc flash detection device 104 and the portable arc flash detection device 106 for wireless communication. To illustrate, because different power control systems in an area may control separate respective electrical equipment, the portable arc flash detection devices 104, 106 may need to establish wireless communication with the relevant power control system, which is the power control system 102 in this embodiment. For example, in response to a wireless pairing process initiated by the portable arc flash detection device 104, the breaker control system 126 of the power control system 102 may pair with the portable arc flash detection device 104, and in response to a wireless pairing process initiated by the portable arc flash detection device 106, the breaker control system 126 may pair with the portable arc flash detection device 106. The particular pairing process to establish wireless communication depends on the particular wireless communication technology as can be readily understood by those of ordinary skill in the art with the benefit of this disclosure. For example, the portable arc flash detection devices 104, 106 and the breaker control system 126 may use a wireless communication technology, such as LoRaWAN, BLE, Wi-Fi, etc.

In some example embodiments, the breaker control system 126 may control the trip the circuit breaker 124 based on both a flash detection message from either one of the portable arc flash detection devices 104, 106 and a detection of a rapid current surge. A rapid current surge may correspond to a rate of change in current that corresponds to an arc flash event (e.g., 1000% increase in current in less than 10 millisecond). For example, the rapid current surge may be detected using a current transformer (CT) on the main power connection (i.e., before the circuit breaker 124) or on the breaker controlled power line (i.e., after the circuit breaker 124) as can be readily understood by those of ordinary skill in the art with the benefit of this disclosure. If the breaker control system 126 detects a rapid current surge before or after receiving, within a threshold time period (e.g., 15 milliseconds), a flash detection message indicating that a flash of light is detected, the breaker control system 126 may trip the circuit breaker 124 to disconnect the main power from the electrical equipment 114, 120.

To be clear, in some example embodiments, the breaker control system 126 may trip the circuit breaker 124 if the breaker control system 126 receive a flash detection message indicating the detection of a flash of light even if a rapid current surge is not detected within the threshold time before or after the receipt of the flash detection message. Alternatively, the breaker control system 126 may not trip the circuit breaker 124 even if the breaker control system 126 receives a flash detection message indicating the detection of a flash of light unless a rapid current surge is detected within the threshold time before or after the receipt of the flash detection message. In some example embodiments, the breaker control system 126 may not trip the circuit breaker 124 even if a rapid current surge is detected unless the flash detection message indicating the detection of a flash of light is received by the breaker control system 126 with the threshold time.

In some example embodiments, the breaker control system 126 may provide an alert notification indicating the detection of an arc flash. For example, upon determining that the flash detection message wirelessly received from either one of the portable arc flash detection devices 104, 106 indicates the detection of a flash of light, the breaker control system 126 may trip the circuit breaker 124 as described above and transmit an alert notification wirelessly, for example, to a remote location. Alternatively or in addition, the breaker control system 126 may provide a visual (e.g., flashing light) and/or audio notification to indicate the detection of an arc flash. Alternatively, the breaker control system 126 may provide the alert notification upon the detection of the flash of light as indicated by the flash detection message from either one of the portable arc flash detection devices 104, 106 as well as the detection of a rapid current surge as described above.

By using flash detection messages transmitted wirelessly by the portable arc flash detection device 104, 106, the arc flash detection and power control system 100 can quickly detect arc flashes and reduce clearing time that can reduce the injury to electrical workers and damage to electrical equipment such as the electrical equipment 114, 120. Because the portable arc flash detection devices 104, 106 can be easily attached to clothing, cabinets, etc., the ability to quickly detect arc flashes and mitigate damage can be readily included in existing or new electrical installations. The portability of the portable arc flash detection device 104, 106 provides the flexibility to use the portable arc flash detection devices 104, 106 at different locations.

In some example embodiments, the portable arc flash detection devices 104, 106 may be calibrated using a calibration device 130. For example, the calibration device 130 may produce a light with sufficient lux to test the portable arc flash detection devices 104, 106 and set the threshold lux level to detect arc flashes.

In some alternative embodiments, the arc flash detection and power control system 100 may include other system components than shown without departing from the scope of this disclosure. For example, the arc flash detection and power control system 100 may include more or fewer pieces of electrical equipment than the electrical equipment 114, 120 than shown without departing from the scope of this disclosure. As another example, the arc flash detection and power control system 100 may include fewer or more portable arc flash detection devices than shown without departing from the scope of this disclosure. In some alternative embodiments, a single breaker controlled power line by be connected to multiple pieces of electrical equipment without departing from the scope of this disclosure. In some alternative embodiments, more or fewer components may be housed in each of the electrical equipment cabinets 118, 128 without departing from the scope of this disclosure. In some alternative embodiments, the power control system 102 may include more or fewer components than shown without departing from the scope of this disclosure. In some alternative embodiments, more than one portable arc flash detection device may be attached to the clothing 108 of the person 110 without departing from the scope of this disclosure. In some alternative embodiments, more than one portable arc flash detection device may be attached to the electrical equipment cabinet 128 without departing from the scope of this disclosure. In some alternative embodiments, a portable arc flash detection device may be attached to the electrical equipment cabinet 118 without departing from the scope of this disclosure.

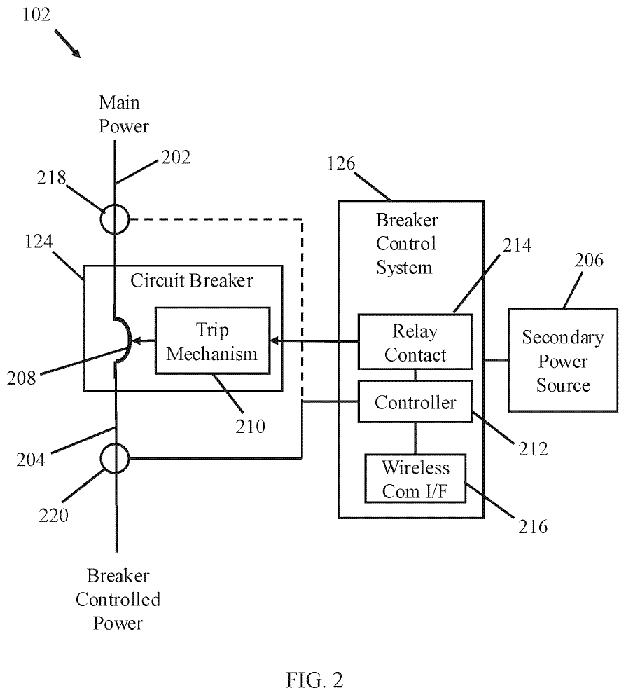

FIG. 2 illustrates the power control system 102 of the arc flash detection and power control system 100 of FIG. 1 according to an example embodiment. Referring to FIGS. 1 and 2, in some example embodiments, the power control system 102 includes the circuit breaker 124 and the breaker control system 126. The power control system 102 may also include a secondary power source 206 that may provide power to the breaker control system 126. For example, the secondary power source 206 may be a battery. In general, the secondary power source 206 provides power to at least some of the components of the breaker control system 126 independent of the main power that is delivered to the circuit breaker 124 via an electrical connection 202.

In some example embodiments, the circuit breaker 124 may include a breaker contact 208 that is normally closed allowing the main power on the electrical connection 202 to be delivered to electrical equipment 114, 120 through the circuit breaker 124 via an electrical connection 204 (e.g., an electrical cable). The main power on the electrical connection 202 is referred to herein as breaker controlled power on the electrical connection 204 after the circuit breaker 124 for clarity of description.

In some example embodiments, the circuit breaker 124 may also include a trip mechanism 210 that can trip (i.e., open) the breaker contact 208. The trip mechanism 210 may include a manual switch, a coil, and/or other structures that can be used to trip/open the breaker contact 208. For example, the trip mechanism 210 may trip/open the breaker contact 208 based on electrical or electromagnetic input from the breaker control system 126.

In some example embodiments, the breaker control system 126 may include a controller 212, a relay contact 214, and a wireless communication interface 216. For example, the controller 212 may include a microcontroller and a memory device, where the microcontroller executes software code stored in the memory device to perform some of the operations described herein with respect to the controller 212.

In some example embodiments, the controller 212 may receive flash detection messages from the portable arc flash detection devices 104, 106 via the wireless communication interface 216. The wireless communication interface 216 may support one or more wireless communication technologies such as LoRaWAN, BLE, Wi-Fi, etc. To illustrate, the wireless communication interface 216 may include a transmitter, a receiver, and/or a transceiver as well as an antenna that can be used to transmit and receive signals wirelessly.

In some example embodiments, the controller 212 may process a received flash detection message to determine whether the flash detection message indicates that a flash of light is detected. For example, the controller 212 may process a flash detection message received from the portable arc flash detection device 104 and determine whether the flash detection message indicates that a flash of light is detected. Upon determining that a received flash detection message from the portable arc flash detection device 104 indicates that a flash of light is detected, the controller 212 may cause the relay contact 214 to close and thus establishing an electrical path for power from the secondary power source 206 to trigger the trip mechanism 210 of the circuit breaker 124. As described above, the trip mechanism 210 may trip/open the breaker contact 208 and thereby disconnecting the main power on the electrical connection 202 from the electrical connection 204. For example, the electrical connection 204 may be electrically connected to one or more pieces of downstream electrical equipment such as the electrical equipment 114, 120.

As another example, the controller 212 may process a flash detection message received from the portable arc flash detection device 106 and determine whether the flash detection message indicates that a flash of light is detected. Upon determining that a received flash detection message from the portable arc flash detection device 106 indicates that a flash of light is detected, the controller 212 may cause the relay contact 214 to close and thus establishing an electrical path for power from the secondary power source 206 to trigger the trip mechanism 210 of the circuit breaker 124. As described above, the trip mechanism 210 may trip/open the breaker contact 208 and thereby disconnecting the main power on the electrical connection 202 from the electrical connection 204.

In some example embodiments, the controller 212 may receive an input signal from a CT 220 senses the current flowing through the electrical connection 204 (e.g., an electrical cable). For example, the CT 220 may provide to the controller 212 an analog signal indicative of the current flowing through the electrical connection 202. The controller 212 may include one or more components, such as an analog-to-digital converter, that can convert the analog signal from the CT 220 into a digital signal that can be processed by the controller 212 to detect or otherwise determine the occurrence of a rapid current surge on the electrical connection 204. Because an arc flash may be associated with a rapid current surge, the detection of a rapid current surge may be used as a confirmation that a flash of light detected by either one of the portable arc flash detection devices 104, 106 is indeed an arc flash.

To illustrate, in some example embodiments, the controller 212 may trip the circuit breaker 124, i.e., close the relay contact 214 to trigger the trip mechanism 210 of the circuit breaker 124, in response to not just one but both a detection of a rapid current surge and a detection of a flash of light. For example, if a rapid current surge is detected within a threshold time before or after the controller 212 determines that a flash of light is detected by either one of the portable arc flash detection devices 104, 106, the breaker control system 126 may trip the circuit breaker 124 as described above. If the controller 212 does not detect a rapid current surge within a threshold time after determining from a received flash detection message that a flash of light is detected, the breaker control system 126 may not trip the circuit breaker 124 to disconnect power from downstream electrical equipment, such as the electrical equipment 114, 120.

To be clear, in some example embodiments, the breaker control system 126 may trip the circuit breaker 124 if the controller 212 receive a flash detection message indicating the detection of a flash of light even if a rapid current surge is not detected within the threshold time before or after the receipt of the flash detection message. In some example embodiments, the breaker control system 126 may not trip the circuit breaker 124 even if a rapid current surge is detected unless the controller 212 determines within the threshold time from the detection of the rapid current surge that a flash of light is detected by either one of the portable arc flash detection devices 104, 106.

In some alternative embodiments, the power control system 102 may include more or fewer components than shown without departing from the scope of this disclosure. In some alternative embodiments, a CT 218 may be used instead of the CT 220 to detect current surges. For example, the CT 218 may be used to detect rapid current surges on the electrical connection 202 and the CT 220 may be omitted without departing from the scope of this disclosure. In some alternative embodiments, both CTs 218, 220 may be omitted without departing from the scope of this disclosure. In some alternative embodiments, some of the components of the power control system 102 may be integrated into a single component without departing from the scope of this disclosure. In some alternative embodiments, the circuit breaker 124 and the breaker control system 126 may include more, fewer, and/or different components than shown without departing from the scope of this disclosure. In some alternative embodiments, the components of the power control system 102 may be connected in a different configuration than shown without departing from the scope of this disclosure. In some alternative embodiments, the circuit breaker 124 and the breaker control system 126 may each be connected in a different configuration than shown without departing from the scope of this disclosure.

In some alternative embodiments, the portable arc flash detection devices 104, 106 may each include a pressure sensor to detect the pressure produced during an arc fault event that results in an arc flash, and the portable arc flash detection devices 104, 106 may transmit a pressure detection message indicating the detection of such pressure in the same manner as described with respect to the flash of light that corresponds to an arc flash. The power control system 102 may receive the pressure detection message and control the power provided through the circuit breaker 124 in the same manner as described with respect to the flash detection message. In some alternative embodiments, the portable arc flash detection devices 104, 106 may each include a sound sensor to detect the sound produced during an arc fault event that results in an arc flash, and the portable arc flash detection devices 104, 106 may transmit a message indicating the detection of such sound in the same manner as described with respect to the flash of light that corresponds to an arc flash. The power control system 102 may receive the sound detection message and control the power provided through the circuit breaker 124 in the same manner as described with respect to the flash detection message.

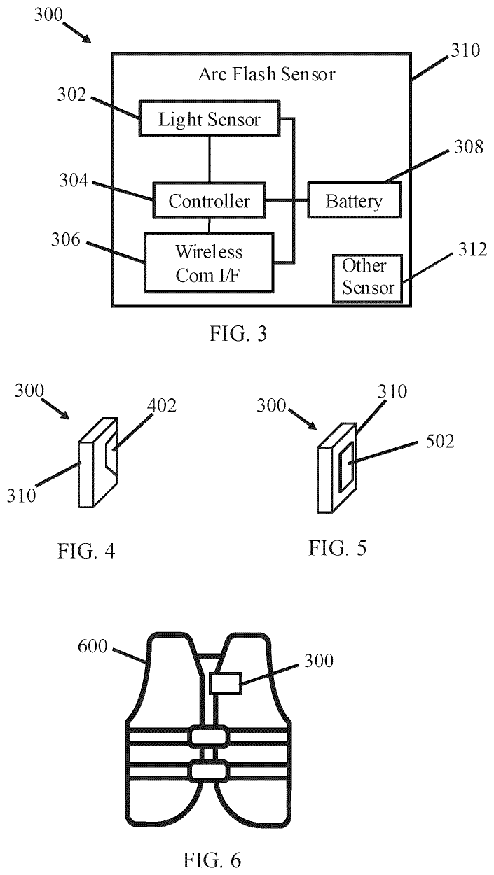

FIG. 3 illustrates a portable arc flash detection device 300 of the arc flash detection and power control system 100 of FIG. 1 according to an example embodiment. For example, the portable arc flash detection device 300 may correspond to each one of the portable arc flash detection device 104, 106 shown in FIG. 1. Referring to FIGS. 1-3, in some example embodiments, the portable arc flash detection device 300 may include a light sensor 302, a controller 304, and a wireless communication interface 306. The portable arc flash detection device 300 may also include a battery to provide electrical power to the light sensor 302, the controller 304, and/or the wireless communication interface 306. The light sensor 302, the controller 304, the wireless communication interface 306, and the battery 308 may be inside a housing 310. For example, the housing 310 may be made from plastic and/or another suitable material. In general, the portable arc flash detection device 300 may be suitable for use in a hazardous classified area. For example, the portable arc flash detection device 300 may be certified (e.g., FM certified and/or UL certified) for use in hazardous areas.

In some example embodiments, the light sensor 302 may be an optical sensor that converts light energy to electrical energy. For example, the electrical energy from the light sensor may be provided to the controller 304 as an electrical signal, and the controller 304 may process the electrical signal to determine whether the electrical signal indicates a flash of light having an intensity level corresponding to an arc flash. For example, the controller 304 may determine whether an arc flash is captured by the optical sensor 302 based on the amplitude of the electrical signal from the optical sensor 302. To illustrate, the controller 304 may determine whether the intensity level of the flash of light exceeds a threshold lux level (e.g., 50 k lux, or higher) based on the amplitude of the electrical signal as can be readily understood by those of ordinary skill in the art with the benefit of this disclosure. To illustrate, the controller 304 may include an analog-to-digital converter, a memory device, and a microprocessor as well as other components. The controller 304 may transmit a flash detection message wirelessly via the wireless communication interface 306 indicating whether a flash of light is detected by the portable arc flash detection device 300. For example, the controller 304 may transmit the flash detection message when a flash of light having an intensity level corresponding to an arc flash is detected. In some example embodiments, the portable arc flash detection device 300 may be calibrated using the calibration device 130 shown in FIG. 1. The calibration device 130 may produce a light with sufficient lux to test the portable arc flash detection device 300, for example, to set the threshold lux level such that the portable arc flash detection device 300 can distinguish arc flashes from other flashes of light.

In some example embodiments, the controller 304 may initiate a wireless pairing process through the wireless communication interface 306 to establish wireless communication with the power control system 102 before transmitting a flash detection message. For example, the wireless communication interface 306 may support one or more wireless communication technologies such as LoRaWAN, BLE, Wi-Fi, etc. To illustrate, the wireless communication interface 306 may include a transmitter, a receiver, and/or a transceiver as well as an antenna that can be used to transmit and receive signals wirelessly.

In some example embodiments, the portable arc flash detection device 300 may include other component than shown without departing from the scope of this disclosure. For example, the portable arc flash detection device 300 may include a user interface (not shown) such as a button, a keypad, etc. that can be used by a person to provide an input to the portable arc flash detection device 300. To illustrate, a person may provide an input to the portable arc flash detection device 300 to initial a wireless pairing process. In some alternative embodiments, the portable arc flash detection device 300 may include more, fewer, or different components than shown without departing from the scope of this disclosure. In some alternative embodiments, some of the components of the portable arc flash detection device 300 may be integrated into a single component without departing from the scope of this disclosure. In some alternative embodiments, the components of the portable arc flash detection device 300 may be connected in a different configuration than shown without departing from the scope of this disclosure.

In some alternative embodiments, the portable arc flash detection device 300 may include a second sensor 312. For example, the second sensor 312 may be a pressure sensor that detects the pressure produced as result of an arc fault event resulting in an arc flash. The portable arc flash detection device 300 may transmit a pressure detection message indicating the detection of such pressure in the same manner as described with respect to the flash of light that corresponds to an arc flash. As another example, the second sensor 312 may be a sound sensor that detects the sound produced as result of an arc fault event resulting in an arc flash. The portable arc flash detection device 300 may transmit a sound detection message indicating the detection of such sound in the same manner as described with respect to the flash of light that corresponds to an arc flash.

In some example embodiments, the portable arc flash detection device 300 may be calibrated with the calibration device 130. For example, the calibration device 130 may produce sufficient pressure and/or sound to test the portable arc flash detection device 300, for example, to set the threshold pressure (e.g., PSI) and/or decibel level such that the portable arc flash detection device 300 can distinguish arc flashes from other pressure or sound waves.

FIG. 4 illustrates the portable arc flash detection device 300 of FIG. 3 according to an example embodiment. Referring to FIGS. 1-4, in some example embodiments, the portable arc flash detection device 300 may include the housing 310 that houses the light sensor 302, the controller 304, the wireless communication interface 306, and the battery 308 as described above. The portable arc flash detection device 300 may also include a clip 402 that may be used to attach the portable arc flash detection device 300 to clothing, such as a vest, a jacket, pants, etc. as may be suitable in a particular application. To illustrate, the clip 402 may be pulled or pressed on one end and released to securely attach the portable arc flash detection device 300 to clothing such the clothing 108 (shown in FIG. 1). For example, the portable arc flash detection device 106 (shown in FIG. 1), which may correspond to the portable arc flash detection device 300 as shown in FIG. 4, may be attached to the clothing 108 using the clip 402. In general, the clip 402 may be integrally formed with the housing 310 or may be attached, for example, by one or more fasteners, such as screws.

In some alternative embodiments, the clip 402 may be at a different location than shown in FIG. 4 without departing from the scope of this disclosure. In some alternative embodiments, the clip 402 may be a different type of clip than shown without departing from the scope of this disclosure. In some alternative embodiments, the portable arc flash detection device 300 may include multiple clips that are used to attach the portable arc flash detection device to clothing or other objects without departing from the scope of this disclosure.

FIG. 5 illustrates the portable arc flash detection device 300 of FIG. 3 according to another example embodiment. Referring to FIGS. 1-3 and 5, in some example embodiments, the portable arc flash detection device 300 may include the housing 310 that houses the light sensor 302, the controller 304, the wireless communication interface 306, and the battery 308 as described above. The portable arc flash detection device 300 may also include a magnet 502 for magnetically attaching the portable arc flash detection device 300 to a structure such as the electrical equipment cabinet 128 (shown in FIG. 1).

For example, the magnet 502 may be attached to the housing 310 on the outside or inside of the housing 310. The magnet 502 may be attached to the housing 310, for example, using an adhesive or another attachment means as can be readily understood by those of ordinary skill in the art with the benefit of this disclosure. The portable arc flash detection device 104 (shown in FIG. 1), which may correspond to the portable arc flash detection device 300 as shown in FIG. 5, may be attached to the clothing 108 using the magnet 502.

In some alternative embodiments, the magnet 502 may be at a different location than shown in FIG. 5 without departing from the scope of this disclosure. In some alternative embodiments, the magnet 502 may be an array of magnets without departing from the scope of this disclosure. In some alternative embodiments, the portable arc flash detection device 300 may include another component instead of or in addition to the magnet 502 for attaching the portable arc flash detection device 300 to an object such as clothing and an electrical equipment cabinet without departing from the scope of this disclosure. For example, the portable arc flash detection device 300 may include Velcro or another attachment device.

FIG. 6 illustrates the portable arc flash detection device 300 of FIG. 4 attached to clothing 600 according to an example embodiment. For example, the portable arc flash detection device 300 may correspond to the portable arc flash detection device 106 shown in FIG. 1. For example, the portable arc flash detection device 300 may be clipped to the clothing 600 using the clip 402 shown in FIG. 4. In some alternative embodiments, the portable arc flash detection device 300 may be attached to the clothing 600 at a different location than shown without departing from the scope of this disclosure.

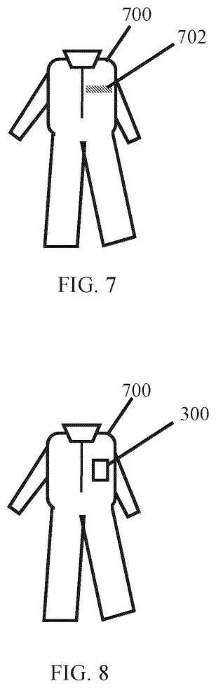

FIG. 7 illustrates an attachment apparatus 702 for attaching the portable arc flash detection device 300 of FIG. 3 to clothing 700 according to an example embodiment. For example, the attachment apparatus 702 may be a Velcro piece attached (e.g., sewn or glued) to the clothing 700. FIG. 8 illustrates the portable arc flash detection device 300 of FIG. 3 attached to the clothing 700 of FIG. 7 using the attachment apparatus 702 according to an example embodiment. In some alternative embodiments, the attachment apparatus 702 may include multiple Velcro pieces without departing from the scope of this disclosure. In some alternative embodiments, the attachment apparatus 702 may be at a different location than shown without departing from the scope of this disclosure.

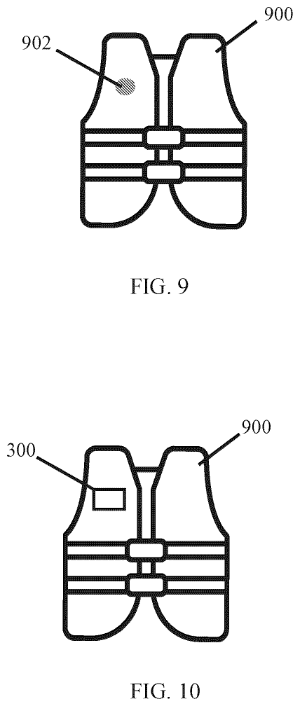

FIG. 9 illustrates an attachment apparatus 902 for attaching the portable arc flash detection device 300 of FIG. 3 to clothing 900 according to an example embodiment. For example, the attachment apparatus 902 may be a clip that can be used to attach the portable arc flash detection device 300 to the clothing 900. FIG. 10 illustrates the portable arc flash detection device 300 of FIG. 3 attached to the clothing 900 of FIG. 9 using the attachment apparatus 902 according to an example embodiment. In some alternative embodiments, the attachment apparatus 902 may be at a different location than shown without departing from the scope of this disclosure.

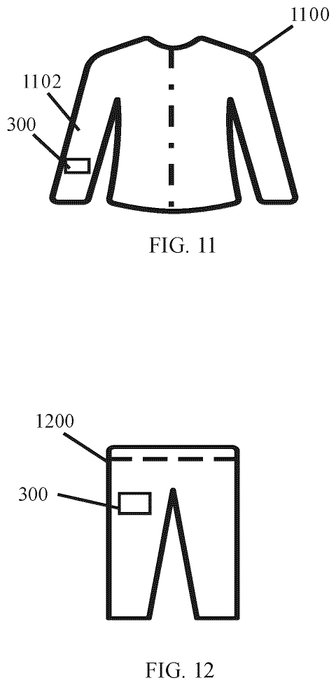

FIG. 11 illustrates the portable arc flash detection device 300 of FIG. 3 attached to clothing 1100 according to another example embodiment. For example, the clothing 1100 may be a jacket, and the portable arc flash detection device 300 may be attached to a sleeve 1102 of the jacket. To illustrate, the portable arc flash detection device 300 may be attached to the sleeve 1102 using the clip 402 of the portable arc flash detection device 300 as shown in FIG. 4, the attachment apparatus 702 shown in FIG. 7, or the attachment apparatus 902 shown in FIG. 9. In some alternative embodiments, the portable arc flash detection device 300 may be attached to the sleeve 1102 using another means without departing from the scope of this disclosure.

FIG. 12 illustrates the portable arc flash detection device 300 of FIG. 3 attached to clothing 1200 according to another example embodiment. For example, the clothing 1100 may be a pant. To illustrate, the portable arc flash detection device 300 may be attached to the clothing 1200 using the clip 402 of the portable arc flash detection device 300 as shown in FIG. 4, the attachment apparatus 702 shown in FIG. 7, or the attachment apparatus 902 shown in FIG. 9. In some alternative embodiments, the portable arc flash detection device 300 may be attached to the clothing 1200 using another means without departing from the scope of this disclosure.

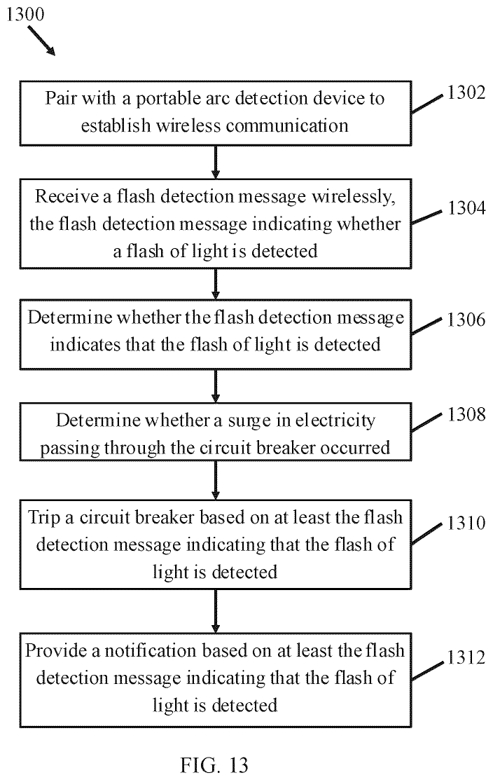

FIG. 13 illustrates an arc flash detection and power control method 1300 according to an example embodiment. Referring to FIGS. 1-13, in some example embodiments, at step 1302, the method 1300 includes pairing, by the breaker control system 126, with the portable arc detection device 104, 106 to establish wireless communication. For example, the pairing processing may be initiated by the portable arc flash detection devices 104, 106 individually. As described above, the portable arc flash detection device 104, 106 may pair with the breaker control system 126 because the breaker control system 126 can trip the circuit breaker 124 that controls electrical power to the electrical equipment 114, 120 that are monitored by the portable arc flash detection devices 104, 106 for arc flashes. To illustrate, a person, such as the person 110 shown in FIG. 1, may provide an input to the portable arc flash detection devices 104, 106 to initiate the pairing process. Alternatively, each one of the portable arc flash detection devices 104, 106 may automatically initiate pairing with the breaker control system 126 upon being powered on, for example, based on wireless signal strength from the breaker control system 126.

In some example embodiments, at step 1304, the method 1300 includes receiving, by the breaker control system 126, a flash detection message wirelessly. For example, the breaker control system 126 may receive the flash detection message from the portable arc flash detection device 104 or 106. The controller 212 of the breaker control system 126 may receive the flash detection message via the wireless communication interface 216. The flash detection message may indicate whether a flash of light (i.e., a flash of light having an intensity level corresponding to an arc flash) is detected by the portable arc flash detection device 104 or 106.

In some example embodiments, at step 1306, the method 1300 includes determining, by the breaker control system 126, whether the flash detection message indicates that the flash of light is detected. For example, the controller 212 of the breaker control system 126 may determine whether the flash detection message indicates that a flash of light is detected. At step 1308, the method 1300 may include determining, by the breaker control system 126, whether a rapid increase in the current passing through the circuit breaker occurred. At step 1310, the method 1300 may include tripping, by the breaker control system 126, the circuit breaker 124 based on at least the flash detection message indicating that the flash of light is detected as determined by the controller 212 of the breaker control system 126. Alternatively, the method 1300 may include tripping the circuit breaker 124 based on at least the flash detection message indicating that the flash of light is detected and a rapid current surge being detected, for example, within a threshold time from each other.

In some example embodiments, at step 1312, the method 1300 includes providing, by the breaker control system 126, a notification based on at least the flash detection message indicating that the flash of light is detected. For example, upon determining that the flash detection message from either one of the portable arc flash detection devices 104, 106 indicates that a flash of light is detected, the controller 212 of the breaker control system 126 may transmit an alert notification to a preprogrammed destination. Alternatively or in addition, the controller 212 may provide visual or audio notification as can be readily understood by those of ordinary skill in the art with the benefit of this disclosure.

In some alternative embodiments, the method 1300 may include more or fewer steps than shown in FIG. 13 without departing from the scope of this disclosure. In some alternative embodiments, some of the steps of the method 1300 may be performed in a different order than described without departing from the scope of this disclosure.

Although some embodiments have been described herein in detail, the descriptions are by way of example. The features of the embodiments described herein are representative and, in alternative embodiments, certain features, elements, and/or steps may be added or omitted. Additionally, modifications to aspects of the embodiments described herein may be made by those skilled in the art without departing from the scope of the following claims, the scope of which are to be accorded the broadest interpretation so as to encompass modifications and equivalent structures.

While particular embodiments are described above, it will be understood it is not intended to limit the invention to these particular embodiments. On the contrary, the invention includes alternatives, modifications and equivalents that are within the spirit and scope of the appended claims. Numerous specific details are set forth in order to provide a thorough understanding of the subject matter presented herein. But it will be apparent to one of ordinary skill in the art that the subject matter may be practiced without these specific details. In other instances, well-known methods, procedures, and components, and circuits have not been described in detail so as not to unnecessarily obscure aspects of the embodiments.

The terminology used in the description of the invention herein is for the purpose of describing particular embodiments only and is not intended to be limiting of the invention. As used in the description of the invention and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, operations, elements, and/or components, but do not preclude the presence or addition of one or more other features, operations, elements, components, and/or groups thereof.

The use of the term “about” applies to all numeric values, whether or not explicitly indicated. This term generally refers to a range of numbers that one of ordinary skill in the art would consider as a reasonable amount of deviation to the recited numeric values (i.e., having the equivalent function or result). For example, this term can be construed as including a deviation of ±10 percent of the given numeric value provided such a deviation does not alter the end function or result of the value. Therefore, a value of about 1% can be construed to be a range from 0.9% to 1.1%. Furthermore, a range may be construed to include the start and the end of the range. For example, a range of 10% to 20% (i.e., range of 10%-20%) includes 10% and also includes 20%, and includes percentages in between 10% and 20%, unless explicitly stated otherwise herein. Similarly, a range of between 10% and 20% (i.e., range between 10%-20%) includes 10% and also includes 20%, and includes percentages in between 10% and 20%, unless explicitly stated otherwise herein.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

It is understood that when combinations, subsets, groups, etc. of elements are disclosed (e.g., combinations of components in a composition, or combinations of steps in a method), that while specific reference of each of the various individual and collective combinations and permutations of these elements may not be explicitly disclosed, each is specifically contemplated and described herein. By way of example, if an item is described herein as including a component of type A, a component of type B, a component of type C, or any combination thereof, it is understood that this phrase describes all of the various individual and collective combinations and permutations of these components. For example, in some embodiments, the item described by this phrase could include only a component of type A. In some embodiments, the item described by this phrase could include only a component of type B. In some embodiments, the item described by this phrase could include only a component of type C. In some embodiments, the item described by this phrase could include a component of type A and a component of type B. In some embodiments, the item described by this phrase could include a component of type A and a component of type C. In some embodiments, the item described by this phrase could include a component of type B and a component of type C. In some embodiments, the item described by this phrase could include a component of type A, a component of type B, and a component of type C. In some embodiments, the item described by this phrase could include two or more components of type A (e.g., A1 and A2). In some embodiments, the item described by this phrase could include two or more components of type B (e.g., B1 and B2). In some embodiments, the item described by this phrase could include two or more components of type C (e.g., C1 and C2). In some embodiments, the item described by this phrase could include two or more of a first component (e.g., two or more components of type A (A1 and A2)), optionally one or more of a second component (e.g., optionally one or more components of type B), and optionally one or more of a third component (e.g., optionally one or more components of type C). In some embodiments, the item described by this phrase could include two or more of a first component (e.g., two or more components of type B (B1 and B2)), optionally one or more of a second component (e.g., optionally one or more components of type A), and optionally one or more of a third component (e.g., optionally one or more components of type C). In some embodiments, the item described by this phrase could include two or more of a first component (e.g., two or more components of type C (C1 and C2)), optionally one or more of a second component (e.g., optionally one or more components of type A), and optionally one or more of a third component (e.g., optionally one or more components of type B).

Unless defined otherwise, all technical and scientific terms used herein have the same meanings as commonly understood by one of skill in the art to which the disclosed invention belongs. All citations referred herein are expressly incorporated by reference.

Although some of the various drawings illustrate a number of logical stages in a particular order, stages that are not order dependent may be reordered and other stages may be combined or broken out. While some reordering or other groupings are specifically mentioned, others will be obvious to those of ordinary skill in the art and so do not present an exhaustive list of alternatives. Moreover, it should be recognized that the stages could be implemented in hardware, firmware, software or any combination thereof.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A portable arc flash detection device, comprising:
a light sensor configured to detect a flash of light;
a controller configured to receive sensor data from the light sensor; and
a wireless communication unit, wherein the controller is configured to send a flash detection message wirelessly via the wireless communication unit in response to determining that an intensity level of the flash of light exceeds a threshold lux level and wherein the flash detection message indicates whether the flash of light is detected.

2. The portable arc flash detection device of claim 1, further comprising a battery to provide power to one or more components of the portable arc flash detection device.

3. The portable arc flash detection device of claim 1, wherein the flash of light detected by the sensor is representative of an arcing fault related event within an electrical equipment cabinet.

4. The portable arc flash detection device of claim 1, wherein the electrical equipment includes a circuit breaker that is controllable based on the flash detection message.

5. The portable arc flash detection device of claim 1, wherein the portable arc flash detection device is attachable to a clothing of a person.

6. The portable arc flash detection device of claim 1, wherein the portable arc flash detection device is magnetically attachable to an electrical equipment cabinet.

7. The portable arc flash detection device of claim 1, wherein the portable arc flash detection device is configured to be paired with a breaker control system prior to sending the flash detection message.

8. An arc flash detection and power control system, comprising:
a portable arc flash detection device comprising:
a light sensor configured to detect a flash of light at an electrical device;
a controller configured to receive sensor data from the light sensor; and
a wireless communication unit, wherein the controller is configured to send a flash detection message wirelessly via the wireless communication unit in response to determining that an intensity level of the flash of light exceeds a threshold lux level and wherein the flash detection message indicates whether the flash of light is detected; and
a breaker control system configured to receive the flash detection message wirelessly and to trip a circuit breaker at least based on the flash detection message such that power is disconnected from the electrical device.

9. The arc flash detection and power control system of claim 8, wherein the breaker control system is further configured to detect a rapid current surge in the electrical power passing through the circuit breaker and wherein the breaker control system is configured to trip the circuit breaker based on both the arc flash detection message and a detection of the rapid current surge.

10. The arc flash detection and power control system of claim 8, wherein the portable arc flash detection device is configured to be paired with a breaker control system prior to sending the flash detection message.

11. The arc flash detection and power control system of claim 8, wherein the breaker control system is configured to provide an alert notification indicating a detection of an arc flash at least based on the flash detection message indicating that the flash of light is detected.

12. The arc flash detection and power control system of claim 8, wherein the portable arc flash detection device further comprises a battery to provide power to one or more components of the portable arc flash detection device.

13. The arc flash detection and power control system of claim 8, wherein the portable arc flash detection device is attachable to a clothing of a person.

14. The arc flash detection and power control system of claim 8, wherein the portable arc flash detection device is magnetically attachable to an electrical equipment cabinet.

15. The arc flash detection and power control system of claim 8, wherein the portable arc flash detection device is calibrated to set the threshold lux level.

16. A method of arc flash detection and power control, the method comprising:
receiving, by a breaker control system, a flash detection message wirelessly, wherein the flash detection message indicates whether a flash of light having an intensity level that exceeds a threshold lux level is detected by a portable flash detection device at an electrical device;
determining, by the breaker control system, whether the flash detection message indicates that the flash of light that exceeds the threshold lux level is detected; and
tripping, by the breaker control system, a circuit breaker based on at least the flash detection message such that power is disconnected from the electrical device.

17. The method of claim 16, further comprising providing an alert notification indicating a detection of an arc flash at least based on the flash detection message indicating that the flash of light is detected.

18. The method of claim 16, further comprising pairing, by the breaker control system, with the portable arc flash detection device before receiving the flash detection message.

19. The method of claim 16, further comprising determining whether an occurrence of a rapid current surge in the electrical power passing through the circuit breaker, wherein the tripping the circuit breaker is performed based on both the arc flash detection message and a detection of the rapid current surge.

20. The method of claim 16, wherein the portable flash detection device is calibrated to set the threshold lux level.
